(19) United States
(12) Patent Application Publication
(10) Pub. No.: US 2024/0178178 A1
(43) Pub. Date: May 30, 2024

(54) SEMICONDUCTOR DEVICE AND CORRESPONDING METHOD

(71) Applicant: STMicroelectronics International N.V., Geneva (CH)

(72) Inventors: Francesca DE VITI, Milano (IT); Damian HALICKI, Agrate Brianza (IT); Giovanni GRAZIOSI, Vimercate (IT); Michele DERAI, Milano (IT)

(73) Assignee: STMicroelectronics International N.V., Geneva (CH)

(21) Appl. No.: 18/522,909

(22) Filed: Nov. 29, 2023

(30) Foreign Application Priority Data
Nov. 30, 2022 (IT) 102022000024699

(51) Int. Cl. H01L 23/00; H01L 23/31; H01L 25/16

(52) U.S. Cl. CPC H01L 24/24; H01L 23/3121; H01L 24/19; H01L 24/25; H01L 25/16; H01L 2224/19; H01L 2224/24195; H01L 2224/2501; H01L 2924/1205

(57) ABSTRACT

An integrated circuit semiconductor dice has first and second opposed surfaces. First and second electrically conductive patterns extending at the first and second opposed surfaces provide electrical coupling to the semiconductor die. An electrical component, such as a capacitor, having a length transverse to the first and second opposed surfaces of the semiconductor die, extends bridge-like between the first and second opposed surfaces. Opposed electrical contact end terminals of the electrical component are coupled to the first and second electrically conductive patterns. The electrical component is thus electrically coupled to the semiconductor die via the first and second electrically conductive patterns at the first and second opposed surfaces.

### PRIORITY CLAIM

This application claims the priority benefit of Italian Application for Patent No. 102022000024699 filed on Nov. 30, 2022, the content of which is hereby incorporated by reference in its entirety to the maximum extent allowable by law.

### TECHNICAL FIELD

The description relates to manufacturing semiconductor devices.

Solutions as described herein can be applied to (integrated circuit) semiconductor devices with passive components, for automotive products, for instance.

### BACKGROUND

Passive components like capacitors are extensively used in mixed-signal or power integrated circuit devices.

These passive components can be mounted on the surface of printed circuit boards (PCB), via surface mounting technology (SMT), for instance. In order to reduce the footprint on (and the complexity of) the PCB, a tendency exists towards including these components in the package of the device (this approach is oftentimes referred to as a “system in package” (SiP) approach).

Embedding passive components in standard leadframe packages may turn out to be difficult from the point of view of the assembly process as this may involve customized leadframes or substrates.

Moreover, standard interconnection using wires may lead to constraints in terms of electrical performance and package footprint dimensions and may reduce layout flexibility in case of packages with embedded passive components.

There is a need in the art for solutions aimed at addressing the issues discussed in the foregoing.

### SUMMARY

One or more embodiments relate to an (integrated circuit) semiconductor device.

One or more embodiments relate to a corresponding method.

Solutions as described herein provide a manufacturing process to integrate surface mounting devices (SMD) in the package.

In solutions as described herein, SMD may be vertically mounted on a carrier (e.g., a tape), beside a die or chip, thus reducing the footprint on the package.

Solutions as described herein may be advantageously applied in both wafer level packaging (WLP) and panel level packaging (PLP) manufacturing processes.

In an embodiment, a device comprises: at least one semiconductor die having first and second opposed surfaces; first and second electrically conductive patterns configured to provide electrical coupling to the at least one semiconductor die, the first and second electrically conductive patterns extending at the first and second opposed surfaces of the at least one semiconductor die, respectively; and at least one electrical component having a length transverse to the first and second opposed surfaces of the at least one semiconductor die, the at least one electrical component extending between the first and second opposed surfaces of the at least one semiconductor die and having opposed electrical contact end terminals coupled to the first and second electrically conductive patterns at the first and second opposed surfaces of the at least one semiconductor die, wherein the at least one electrical component is electrically coupled to the at least one semiconductor die via the first and second electrically conductive patterns at the first and second opposed surfaces of the at least one semiconductor die.

In an embodiment, a method comprises: providing, at opposed first and second surfaces of at least one semiconductor die, first and second electrically conductive patterns extending at the first and second opposed surfaces of the at least one semiconductor die, respectively, to provide electrical coupling to the at least one semiconductor die; and arranging, preferably sidewise of the at least one semiconductor die, at least one electrical component with a length transverse to the first and second opposed surfaces of the at least one semiconductor die, the at least one electrical component extending between the first and second opposed surfaces of the at least one semiconductor die and having opposed electrical contact end terminals coupled to the first and second electrically conductive patterns at the first and second opposed surfaces of the at least one semiconductor die, wherein the at least one electrical component is electrically coupled to the at least one semiconductor die via the first and second electrically conductive patterns at the first and second opposed surfaces of the at least one semiconductor die.

### BRIEF DESCRIPTION OF THE DRAWINGS

One or more embodiments will now be described, by way of example only, with reference to the annexed figures, wherein:

FIGS. 1 to 3 are illustrative of a sequence of processing steps in (integrated circuit) semiconductor devices manufacturing process taking place at a wafer level;

FIGS. 4 to 12 are illustrative of a sequence of steps in processing semiconductor devices taking place at a wafer or a panel level;

FIG. 13 is illustrative of a semiconductor device according to embodiments of the present description; and

FIGS. 14 and 15 are illustrative of various SMD arrangements in the package of a semiconductor device.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The headings/references used herein are provided merely for convenience and hence do not define the extent of protection or the scope of the embodiments.

For simplicity and ease of explanation, throughout this description, and unless the context indicates otherwise, like parts or elements are indicated in the various figures with like reference signs, and a corresponding description will not be repeated for each and every figure.

As already mentioned, electrical passive components such as, for instance, capacitors are conventionally mounted on a surface of a printed circuit board (PCB) via the so-called surface mounting technology (SMT). These components are generally referred to as surface mounted devices (SMDs)

A tendency exists towards including these components in the package of the (integrated circuit, IC) semiconductor device. This approach, oftentimes referred to as SiP (System in Package), aims at reducing device footprints on the PCB (and the related complexity): this facilitates meeting the desirability of miniaturized devices.

Mounting an SMD on a PCB, and possibly electrically coupling the SMD to a die or chip in the package, e.g., via wire bonding, may adversely affect electrical performance and/or introduce undesired resistances.

European Patent No. 3,686,928 B1, assigned to the same assignee of the present application, discloses a solution for integrating a SMD into the package of an IC semiconductor device. More specifically, that document discloses a semiconductor device comprising one or more semiconductor chips, a leadframe comprising a chip mounting portion having the semiconductor chip(s) thereon and one or more leads in the leadframe arranged facing the chip mounting portion. The lead(s) lie in a first plane and the chip mounting portion lies in a second plane, with the first plane and the second plane mutually offset with a gap therebetween. An electrical component (such as a capacitor) is arranged on the chip mounting portion extending, for instance vertically, between the first plane and the second plane.

Such solutions may be advantageously applied to devices provided with an electrically conductive substrate (a leadframe).

Solutions as described herein aim at further extending the solutions described in European Patent No. 3,686,928, by integrating a passive component, such as a capacitor, in the package of a device with no leadframe or substrate.

Solutions as described herein may involve providing a desired electrical coupling (between the chip/die and the SMD, for instance) via electrically conductive traces which replace the wire bonding.

Solutions as described herein further reduce the footprint of the package by arranging an SMD “vertically”, electrically coupled via two metallization layers.

In the following a description is provided of a possible sequence of steps to produce an integrated circuit semiconductor device as described herein.

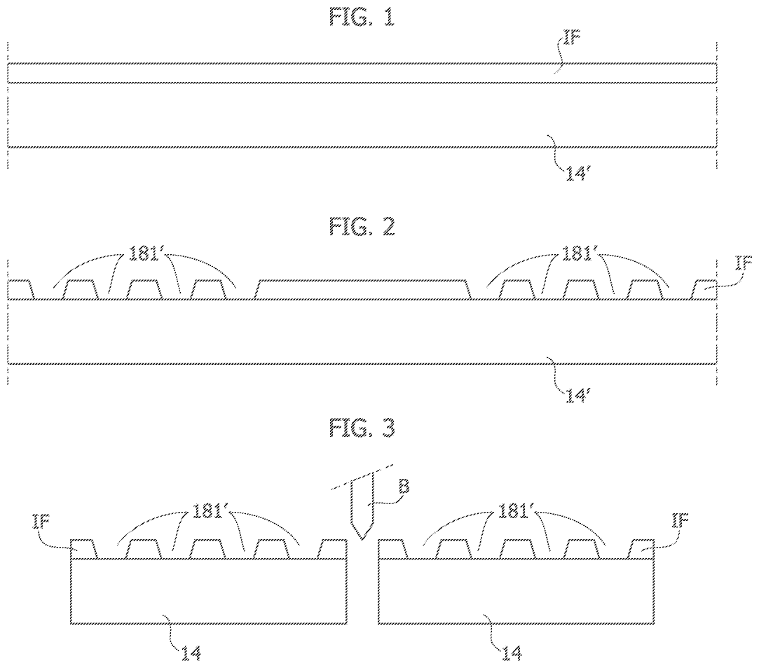

The sequence of steps illustrated in FIGS. 1 to 12 is merely exemplary insofar as: one or more steps as illustrated can be omitted, performed in a different manner (with other tools, for instance) and/or replaced by other steps; additional steps may be added; and one or more steps can be carried out in a sequence different from the sequence illustrated.

FIG. 1 is illustrative of an insulating film IF being provided on a semiconductor (silicon, for instance) wafer 14′ having integrated circuits (ICs), already formed therein in a manner known to those of skill in the art so that these can be concurrently processed. The film IF may be, for instance, an Ajinomoto Build-up Film (ABF) laminated on a first (active) surface of the wafer 14′.

FIG. 2 is illustrative of vias 181′ being opened (e.g., via laser beam processing) through the insulating film IF towards conductive pads on the first surface of the wafer 14′ (these conductive pads are not visible in the figures for scale reasons).

The wafer 14′ is then cut (by sawing with a blade B, for instance) into individual dice or chips 14 in a so-called dicing (or singulation) step. As used herein the terms chip/s and die/dice are regarded as synonymous.

The result of this operation is illustrated in FIG. 3.

The steps illustrated in FIGS. 1 to 3 may take place at wafer level.

After the dicing step, the dice 14 may be arranged on a wafer-shaped or a panel-shaped carrier (e.g., a carrier tape) C1 for further processing: in fact, solutions as described herein may be advantageously applied to both wafer level package (WLP) and panel level package (PLP) processes.

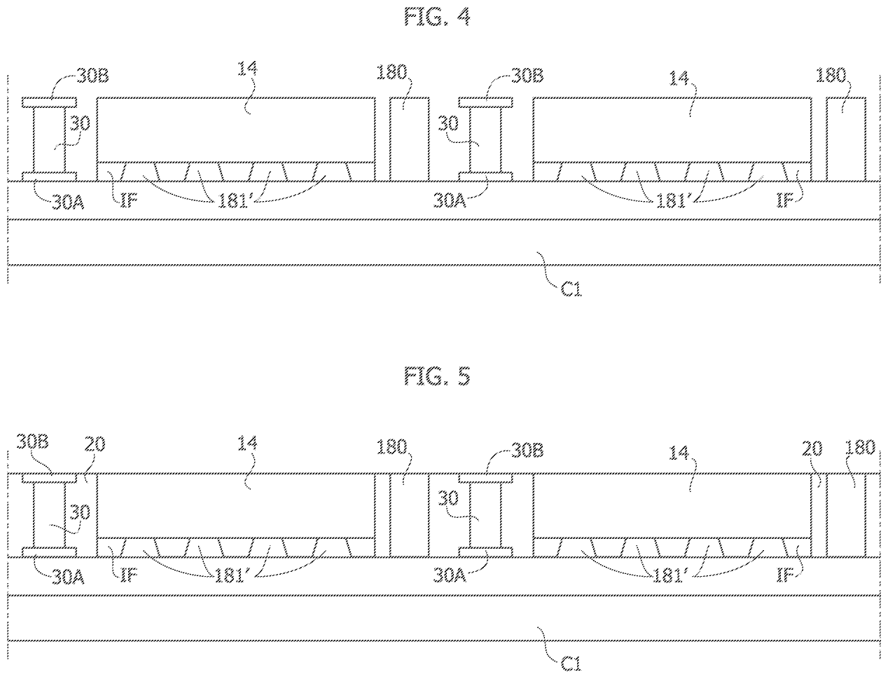

FIG. 4 is illustrative of dice 14 being arranged on a carrier C1 (wafer or panel) allowing for a larger spacing between neighboring dice 14 as conventionally done for fan-out wafer (panel) level packaging processes (FOW(P)LP). The actual size of the fan-out (FO) region may depend on the desired device design.

As illustrated in the figures the carrier C1 (and the carrier C2 discussed in the following) may exhibit a layered structure comprising, e.g.: a base or bottom layer (the carrier proper) of a metal such as stainless steel, for instance; and a front or top layer, such as an adhesive tape, to facilitate precise positioning of dice and passive components on top of the carrier.

In solutions as described herein, the FO region may be advantageously used for arranging passive components such as the component 30 illustrated in FIG. 4.

As exemplified herein, the component 30 may be of elongate form or shape, namely a form that is long in comparison to its width, for instance a length twice the width as is the case of capacitors such as EIA SIZE 0201 or EIA SIZE 0402 capacitors.

The component 30 is a component such as a SMD (surface mount device) which, desirably, is to be included in the package of the final device.

In one or more embodiments, the component 30 (a capacitor, for instance) may be advantageously mounted “vertically”; as used herein, “vertically” means that the component 30 is intended to be mounted with its longest dimension transverse to the carrier C.

As exemplified in the following, electrically coupling of the component 30 may involve providing electrical connection for the (vertical, e.g., upper and lower) ends 30A, 30B of the component 30. Such electrical coupling may be provided via two metallization layers at the two surfaces of the die 14.

In certain cases, in order to electrically couple these two metallization layers, a metallic (e.g., copper) e.g., pillar-like, block 180 may be provided on the carrier C1 in the FO region (that is, beside the die 14).

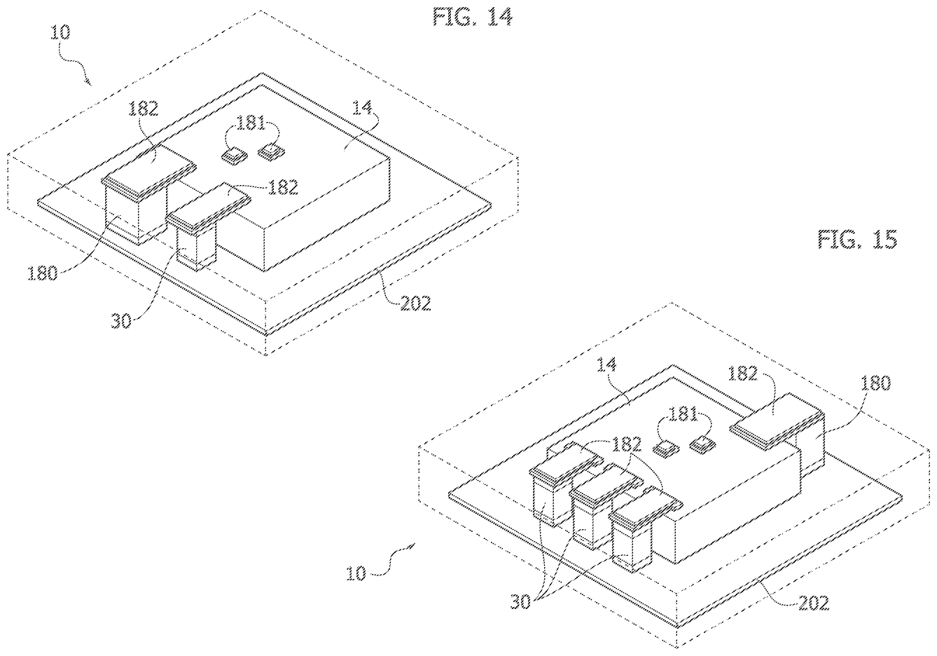

It is noted that the arrangement illustrated in FIG. 4 is merely exemplary: as illustrated later in FIGS. 14 and 15, different arrangements (e.g., different numbers) of dice 14, metallic blocks 180 or (passive) components 30 are possible.

The die 14 illustrated in FIG. 4 is arranged with its first/active surface (that is, the surface with the vias openings 181′ and the insulating film IF laminated thereon) facing/in contact with the carrier C1.

In this way the second surface (that is, the surface opposite to the first surface) of the die 14 is exposed and available for processing.

FIG. 5 is illustrative of a molding step wherein an electrically insulating molding compound 20 (an epoxy resin, for instance) is molded onto the arrangement resulting from the previous steps. The molding step may be followed by grinding of the molding compound 20 in order to trim the second surface (at this stage, the surface opposite to the carrier C1) of the assembly for subsequent processing. As illustrated, this trimming may make the second surface of the molding compound 20 coplanar with the second surface of the die 14, end of the block 180 and end of the components 30.

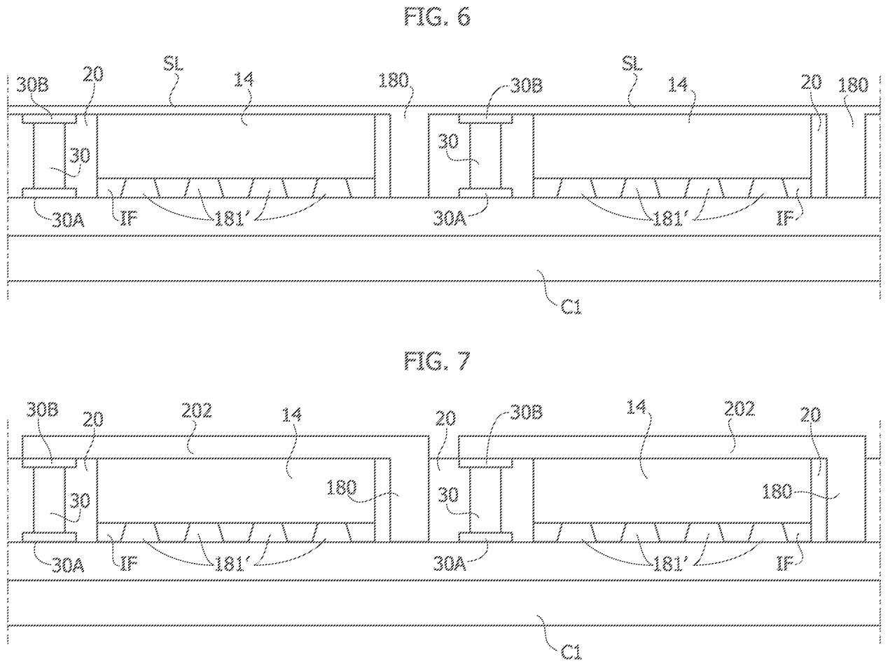

The steps illustrated in FIGS. 6 and 7 provide a metallization layer 202 on the second surface (at this stage, opposite to the carrier C1) of the dice 14 in the assembly resulting from the previous steps.

More to the point, FIG. 6 illustrates the deposition of a seed layer SL over the second surface of the dice 14 in the wafer/panel assembly.

Providing such a seed layer SL may comprise, for instance, depositing a Ti layer followed by a Cu layer. The deposition process may be performed via sputtering deposition, for instance.

The seed layer SL facilitates growing a patterned metallic (e.g., copper) layer 202 (illustrated in FIG. 7) that provides a desired electrical coupling pattern on the second surface of the dice 14.

Such a patterned metallic layer 202 may be formed, for example, via a photolithographic process comprising: laminating a photosensitive dry film (a photoresist film); transferring the desired pattern on the dry film via UV light exposure (via laser direct imaging—LDI—for instance) and development the dry film; growing a metallic (e.g., copper) layer 202 (e.g., via galvanic growth on the seed layer SL left uncovered by the developed dry film); removing the dry film (e.g., via etching); and etching of the Ti/Cu seed layer SL left uncovered by the metallic layer 202.

These steps can be performed in a manner known to those of skill in the art, which makes it unnecessary to provide a more detailed description herein.

As exemplified in FIG. 7, the patterned metallic layer 202 can be provided in such a way as to provide (also) electrical coupling towards (here upper) ends of the component 30 and/or the metallic block 180, according to a desired routing pattern.

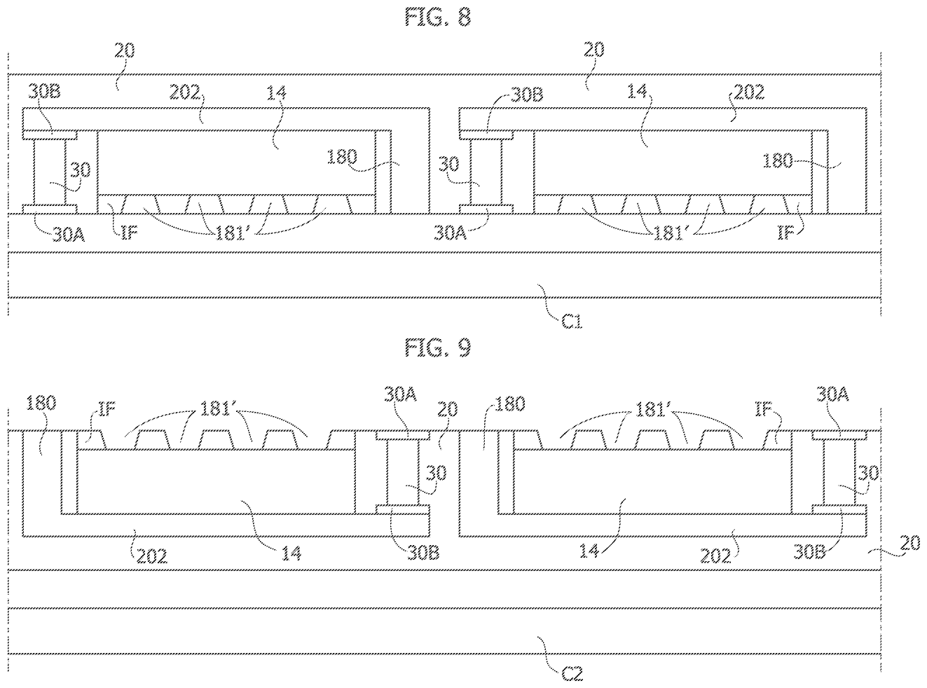

FIG. 8 illustrates the result of a second molding step wherein a further layer of insulating molding compound (e.g., an epoxy resin, still denoted 20 in the figures) is provided on the patterned metallic layer 202 just formed.

FIG. 9 illustrates the wafer/panel being separated from the carrier C1, flipped (turned over) and mounted on a second carrier C2 (this may be identical to the first carrier C1).

In that way, the active (first) surface of the wafer/panel assembly is available for further processing.

Here again, a carrier C2 is represented having a layered structure (e.g., a base or bottom layer and a front or top layer).

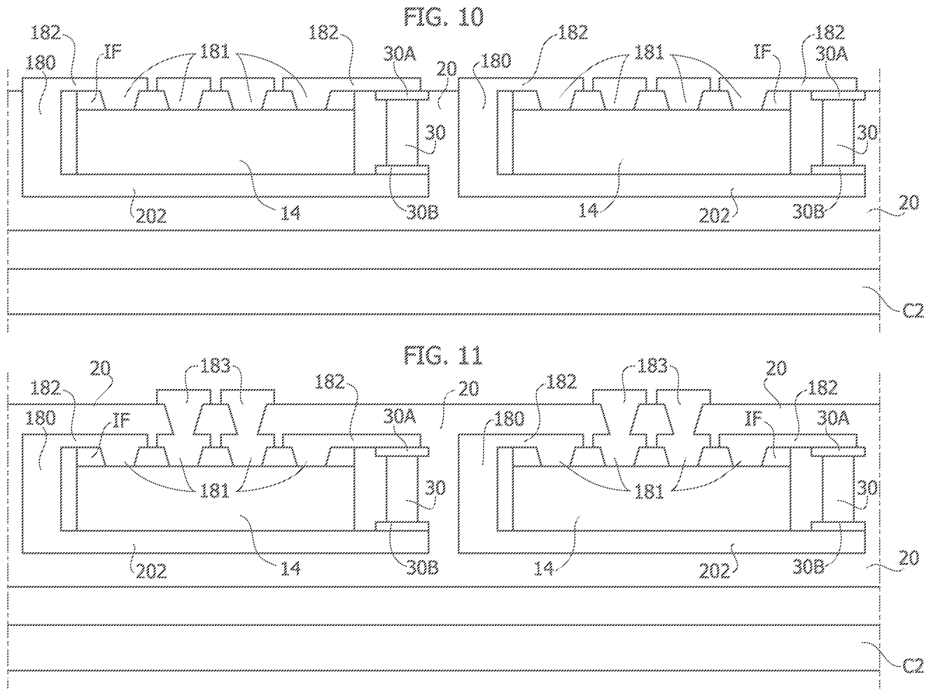

FIG. 10 illustrates a processing step wherein the active/first surface of the dice 14 (now opposite to the carrier C2) in the wafer/panel is provided with electrically conductive vias 181 and traces 182 which form a second patterned metallic (e.g., of copper) layer.

A process similar to the one discussed previously for growing the metallic layer 202 can also be used to grow such a second patterned metallic layer (181, 182).

Electrically conductive traces 182 are used to provide the electrical coupling between selected vias 181 (and the die pads coupled thereto) and to the metallic (e.g., copper) block 180 and/or the (passive) component 30 (e.g., a capacitor) according to a desired routing pattern.

FIG. 11 illustrates input/output, I/O, connections and pads (or studs) 183 being provided on the active (first) surface of the dice 14.

The relate processing may include, for instance: molding further insulating molding compound (e.g., an epoxy resin, once more denoted 20 in the figures for simplicity); re-opening of vias through the mold 20 to the I/O pads 181 of the dice 14, via laser ablation for instance; and growing a metallic (e.g., copper) layer (via a photolithographic process similar to the one already described, for instance).

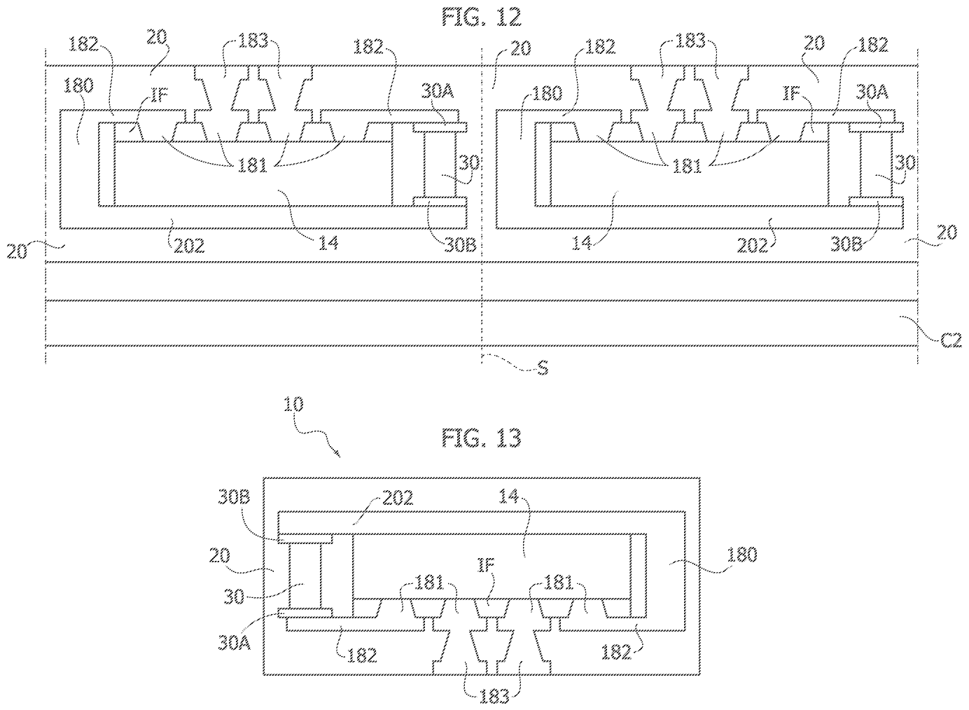

FIG. 12 illustrates the result of a processing step where insulating molding compound (e.g., an epoxy resin, once more denoted 20 in the figures for simplicity) is molded onto the wafer/panel assembly, possibly followed by a final grinding step to refine the surface of the assembly.

Steps as illustrated in FIGS. 10 to 12 can be again implemented in manner known to those of skill in the art, which makes it unnecessary to provide a more detailed description herein.

This also applies to a final singulation step at a cut line S as illustrated in FIG. 12, as performed, e.g., by sawing via a blade (not visible for simplicity).

A method as described herein can be applied to both wafer level packaging (WLP) and panel level packaging (PLP) as the shape and/or size of the carrier does not influence the process.

As already mentioned, the details of the sequence just described shall not be construed in a limiting sense. In particular, certain steps may be performed in a different order than what described so far.

For example, the order in which the two patterned metallic layers 181,182 and 202 are formed may be reverted or, more generally, processing on the two sides/surfaces of the device may be reversed.

FIG. 13 illustrates a singulated device 10 after demounting from the carrier C2.

With reference to FIG. 13, the (integrated circuit) semiconductor devices 10 resulting from the method described herein may have the following structure: at least one (integrated circuit) chip or die 14 having opposed first and second surfaces; two electrically conductive (e.g., metal such as copper) patterns 181, 182 and 202 (single layer or multi-layer) at the opposed first and second surfaces of the chip or die 14; one or more SMDs 30 arranged beside (e.g., sidewise) the die 14, the SMD(s) 30 having an elongate shape and being mounted “vertically”, that is with its length extending bridge-like between the opposed first and second surfaces of the chip or die 14, and (possibly); and one or more electrically conductive (e.g., metal such as copper) blocks 180 extending bridge-like between the opposed first and second surfaces of the chip or die 14.

To summarize, a device 10 as illustrated in FIG. 13 comprises (at least) one semiconductor die 14 having first and second opposed surfaces with a first electrically conductive pattern 181, 182 and a second electrically conductive pattern 202 configured to provide electrical coupling to the semiconductor die 14.

This may occur, e.g., as a result of the first electrically conductive pattern 181, 182 comprising electrically conductive vias extending through the insulating layer IF towards the first (e.g., top or front) surface of the chip or die 14 while the second electrically conductive pattern 202 does not include per se any such conductive pathways to the second (e.g., back or bottom), opposes surface of the chip or die 14. In any case the second electrically conductive pattern 202 is configured to provide electrical coupling to the semiconductor die 14 as result of being connected to the first pattern 181 and/or 182 via the pillar or pillars 180.

As illustrated, the first electrically conductive pattern 181, 182 and the second electrically conductive patterns 202 extend at (over) the opposed surfaces of the semiconductor die 14 with the electrical component 30 arranged “vertically”, that is with a length transverse to the first and second opposed surfaces, extending bridge-like between the opposed surfaces of the semiconductor die 14.

As illustrated, the electrical component 30 has opposed electrical contact end terminals 30A, 30B that are coupled to the first and second electrically conductive patterns 181, 182 and 202 at the first and second opposed surfaces of the semiconductor die 14.

The electrical component 30 is thus electrically coupled to the semiconductor die 14 via the electrically conductive patterns 181, 182, and 202 at the first and second opposed surfaces of the die 14.

As illustrated herein, the two electrically conductive patterns 181, 182 and 202 at the opposed first and second surfaces of the chip or die 14 can be configured to provide a desired connection (routing) to the chip or die 14 as well as a connection to opposite ends 30A, 30B of the one or more SMDs 30 mounted “vertically” beside the chip or die 14 and/or to opposite ends of the blocks (pillars) 180.

Advantageously, the electrical component 30 comprises an elongate component having a major length between its opposed electrical contact end terminals 30A, 30B and is arranged with its major length transverse to the opposed surfaces of the semiconductor die 14.

Still advantageously, the semiconductor die 14 has a thickness between the first and second opposed surfaces (this can be trimmed via wafer grinding as exemplified in FIG. 3) so that the electrical component 30 may have a length transverse to the first and second opposed surfaces of the semiconductor die 14 that is at least approximately equal to the thickness of the semiconductor die 14.

As illustrated, the electrical component 30 can be arranged sidewise of the semiconductor die 14 and the electrically conductive pillar formation 180 may extend bridge-like between the electrically conductive patterns 181, 182, 202 at opposed surfaces of the semiconductor die 14 to provide electrical connection therebetween.

Advantageously, the electrically conductive pillar formation 180 can be arranged sidewise of the semiconductor die 14 and the semiconductor die 14 may thus be possibly located between the electrical component 30 and the conductive formation 180.

As noted, the electrical component 30 may comprise a capacitor, but other electrical components (e.g., resistors) can be uses in the place or in combination with capacitors.

An encapsulation of insulating material 20 (e.g., epoxy resin, possibly provided in subsequent molding steps) may be provided to encapsulate the semiconductor die 14 together with the electrically conductive patterns 181, 182, 202 at the opposed surfaces of the semiconductor die 14.

In that way, the electrical component(s) 30 can be embedded in the encapsulation, and electrically conductive pathways can be formed extending through the encapsulation 20 towards either or both of the electrically conductive patterns 181, 182, 202.

In fact, as illustrated herein, vias/studs 183 (e.g., towards the conductive patterns 181) may provide I/O electrical connections to the device 10.

The plastic package 20 (possibly formed via subsequent molding steps) is provided to protect and insulate the assembly embedded therein.

As mentioned before, the arrangement (e.g., the number) of the (passive) component(s) 30, the metallic block(s) 180 and the die/dice 14 illustrated so far is just by way of example and thus non-limiting of the embodiments.

For instance, arranging the component(s) 30 and/or the block(s) 180 on opposite sides of the chip or die 14 is merely exemplary and non-mandatory.

FIG. 14 (wherein the outline of the molding compound 20 is shown in dashed lines for simplicity) illustrates an arrangement which can be produced via the same method described in the foregoing and wherein a metallic block 180 and a component 30 are located on a same side of a chip or die 14.

Such an arrangement, depending on the desired design may facilitate further reduction of the package size and footprint (on the PCB, for example).

FIG. 15 illustrates another arrangement (here again, the outline of the molding compound 20 is shown in dashed lines for simplicity) wherein multiple components 30 (e.g., three of them) are arranged on a same side of a chip or die 14 and electrically coupled in parallel.

A metallic block 180 is illustrated located on an opposite side of the chip or die 14.

Maintaining a similar arrangement to the one exemplified in FIG. 15, the two patterned metallic layers 181,182 and 202 can be adapted in order that coupling of the passive components 30 can be (at least partly) modified from parallel to series coupling.

Figures such as FIGS. 14 and 15 further highlight the fact that the arrangement (e.g., the number) of the (passive) component(s) 30, the metallic block(s) 180 and the die/dice 14 illustrated herein is just by way of example and thus non-limiting of the embodiments.

The claims are an integral part of the technical teaching provided in respect of the embodiments.

Without prejudice to the underlying principles, the details and embodiments may vary, even significantly, with respect to what has been described by way of example only without departing from the extent of protection. The extent of protection is determined by the annexed claims.

1. A device, comprising:
a semiconductor die having first and second opposed surfaces;
first and second electrically conductive patterns configured to provide electrical coupling to the semiconductor die, wherein the first and second electrically conductive patterns extend at the first and second opposed surfaces of the at least one semiconductor die, respectively;
an electrical component having a length transverse to the first and second opposed surfaces of the semiconductor die, wherein the electrical component extends between the first and second opposed surfaces of the semiconductor die and includes opposed electrical contact end terminals coupled to the first and second electrically conductive patterns at the first and second opposed surfaces of the semiconductor die, respectively;
wherein the electrical component is electrically coupled to the semiconductor die via the first and second electrically conductive patterns at the first and second opposed surfaces of the semiconductor die.

2. The device of claim 1, wherein the electrical component comprises an elongate component having a major length between the opposed electrical contact end terminals, the electrical component being arranged with the major length transverse to the first and second opposed surfaces of the semiconductor die.

3. The device of claim 1, wherein:
the semiconductor die has a thickness between the first and second opposed surfaces; and
the electrical component has a length transverse to the first and second opposed surfaces of the semiconductor die that is at least approximately equal to the thickness of the semiconductor die.

4. The device of claim 1, wherein the electrical component is arranged adjacent a side of the semiconductor die.

5. The device of claim 1, further comprising an electrically conductive formation extending between the first and second electrically conductive patterns at the first and second opposed surfaces of the semiconductor die to provide electrical connection therebetween, wherein the electrically conductive formation is preferably arranged adjacent a side of the semiconductor die.

6. The device of claim 5, wherein the semiconductor die is located between the electrical component and the electrically conductive formation.

7. The device of claim 1, wherein the electrical component comprises a capacitor.

8. The device of claim 1, further comprising an encapsulation of insulating material encapsulating the semiconductor die as well as the first and second electrically conductive patterns at the first and second opposed surfaces of the semiconductor die, wherein the electrical component is embedded in said encapsulation.

9. The device of claim 8, comprising electrically conductive pathways extending through the encapsulation of insulating material towards at least one of the first and second electrically conductive patterns.

10. A method, comprising:
providing, at first and second opposed surfaces of a semiconductor die, first and second electrically conductive patterns extending at the first and second opposed surfaces of the semiconductor die, respectively, to provide electrical coupling to the at least one semiconductor die; and
arranging an electrical component with a length transverse to the first and second opposed surfaces of the semiconductor die;
wherein the electrical component extends between the first and second opposed surfaces of the semiconductor die and has opposed electrical contact end terminals coupled to the first and second electrically conductive patterns at the first and second opposed surfaces of the semiconductor die;
wherein the at electrical component is electrically coupled to the semiconductor die via the first and second electrically conductive patterns at the first and second opposed surfaces of the semiconductor die.

11. The method of claim 10, further comprising arranging an electrically conductive formation extending between the first and second electrically conductive patterns at the first and second opposed surfaces of the semiconductor die to provide electrical connection therebetween.

12. The method of claim 11, wherein the electrical component and the electrically conductive formation are located adjacent opposite sides of the semiconductor die,

13. The method of claim 10, further comprising encapsulating with an encapsulation of insulating material the semiconductor die as well as the first and second electrically conductive patterns at the first and second opposed surfaces of the semiconductor die, wherein the electrical component is embedded in said encapsulation.

14. The method of claim 13, further comprising providing electrically conductive pathways extending through the encapsulation of insulating material towards at least one of the first and second electrically conductive patterns.

15. A method, comprising:
mounting a semiconductor die to a first carrier with a first surface of the semiconductor die facing a surface of the first carrier;
mounting an electrical component having first and second terminals to the first carrier with the first terminal of the electrical component facing the surface of the first carrier, the electrical component having a length which extends transverse to the surface of the first carrier;
encapsulating the semiconductor die and the electrical component in a first encapsulant having a first surface that is coplanar to a second surface of the semiconductor die that is opposed to the first surface and coplanar to the second terminal of the electrical component;
forming a first electrically conductive pattern on the coplanar second surface of the semiconductor die, first surface of the first encapsulant and second terminal of the electrical component, said first electrically conductive pattern making an electrical connection to at least the second terminal of the electrical component;
encapsulating the first electrically conductive pattern in a second encapsulant;
removing the first carrier to expose the first terminal of the electrical component and a second surface of the first encapsulant which is opposite to the first surface of the first encapsulant;
mounting a second carrier to a surface of the second encapsulant;
forming a second electrically conductive pattern on the second surface of the first encapsulant and first terminal of the electrical component, said second electrically conductive pattern making an electrical connection to at least the first terminal of the electrical component; and
encapsulating the second electrically conductive pattern in a third encapsulant.

16. The method of claim 15, wherein said first electrically conductive pattern further makes an electrical connection to pads at the first surface of the semiconductor die.

17. The method of claim 15, further comprising forming electrical contacts which extend through the second encapsulant to make an electrical connection to said first electrically conductive pattern.

18. The method of claim 15, wherein said second electrically conductive pattern further makes an electrical connection to pads at the second surface of the semiconductor die.

19. The method of claim 18, further comprising forming electrical contacts which extend through the third encapsulant to make an electrical connection to said second electrically conductive pattern.

20. The method of claim 15, wherein said electrical component is a capacitor of surface mount device type.
